(19) United States
(12) Patent Application Publication
(10) Pub. No.: US 2024/0243711 A1
(43) Pub. Date: Jul. 18, 2024

(54) AMPLIFIER CIRCUIT AND ELECTRONIC APPARATUS

(71) Applicant: SONY SEMICONDUCTOR SOLUTIONS CORPORATION, KANAGAWA (JP)

(72) Inventor: MASAYUKI SHIMADA, KANAGAWA (JP)

(21) Appl. No.: 18/559,802

(22) PCT Filed: Feb. 3, 2022
(86) PCT No.: PCT/JP2022/004256

§ 371 Date: Nov. 9, 2023

(30) Foreign Application Priority Data
May 26, 2021 (JP) 2021-088784

(51) Int. Cl. H03F 3/24; H03F 1/08

(52) U.S. Cl. CPC H03F 3/245; H03F 1/086; H03F 2200/387

(57) ABSTRACT

An amplifier circuit of the present disclosure includes: an input terminal; an output terminal; one or a plurality of transistors provided on a path that couples the input terminal and the output terminal; an amplitude detection circuit configured to detect a signal amplitude of an input signal at the input terminal; and an impedance circuit configured to change an impedance and set operating conditions of the one or the plurality of transistors on the basis of a detection result of the amplitude detection circuit.

### TECHNICAL FIELD

The present disclosure relates to an amplifier circuit that amplifies a signal, and an electronic apparatus provided with such an amplifier circuit.

### BACKGROUND ART

In a circuit that amplifies a signal, a transistor having multiple stages is often provided. For example, PTL 1 discloses an amplifier circuit including a first-stage transistor, a second-stage transistor, and a capacitor provided between a drain of the first-stage transistor and a source of the second-stage transistor.

### CITATION LIST

### Patent Literature

PTL 1: Japanese Unexamined Patent Application Publication No. 2013-211830

### SUMMARY OF THE INVENTION

Incidentally, a signal having various signal amplitudes may be inputted to an amplifier circuit. In a case where such a signal having the various signal amplitudes is inputted, it is desired that the amplifier circuit is configured to amplify that signal without relying on the signal amplitudes.

It is desirable to provide an amplifier circuit configured to amplify signals having various signal amplitudes, and an electronic apparatus.

An amplifier circuit in an embodiment of the present disclosure includes an input terminal, an output terminal, one or a plurality of transistors, an amplitude detection circuit, and an impedance circuit. The one or the plurality of transistors are provided on a path that couples the input terminal and the output terminal. The amplitude detection circuit is configured to detect a signal amplitude of an input signal at the input terminal. The impedance circuit is configured to change an impedance and set operating conditions of the one or the plurality of transistors on the basis of a detection result of the amplitude detection circuit.

An electronic apparatus in an embodiment of the present disclosure includes a communication circuit. The communication circuit is configured to perform wireless communications and includes an amplifier circuit. The amplifier circuit includes an input terminal, an output terminal, one or a plurality of transistors, an amplitude detection circuit, and an impedance circuit. The one or the plurality of transistors are provided on a path that couples the input terminal and the output terminal. The amplitude detection circuit is configured to detect a signal amplitude of an input signal at the input terminal. The impedance circuit is configured to change an impedance and set operating conditions of the one or the plurality of transistors on the basis of a detection result of the amplitude detection circuit.

In the amplifier circuit and the electronic apparatus in an embodiment of the present disclosure, the one or the plurality of transistors provided on the path that couples the input terminal and the output terminal perform an amplification operation on the basis of the input signal at the input terminal. The amplitude detection circuit detects a signal amplitude of this input signal. Then, the impedance circuit changes the impedance on the basis of the detection result of this amplitude detection circuit. This sets the operating conditions of the one or the plurality of transistors.

### BRIEF DESCRIPTION OF DRAWINGS

FIG. 1 is a circuit diagram illustrating a configuration example of a power amplifier according to an embodiment of the present disclosure.

FIG. 2 is an explanatory diagram illustrating a power amplification operation in the power amplifier illustrated in FIG. 1.

FIG. 3 is another explanatory diagram illustrating the power amplification operation in the power amplifier illustrated in FIG. 1.

FIG. 4A is a circuit diagram illustrating a configuration example of an impedance control circuit illustrated in FIG. 1.

FIG. 4B is another circuit diagram illustrating a configuration example of the impedance control circuit illustrated in FIG. 1.

FIG. 5 is other circuit diagram illustrating a configuration example of the impedance control circuit illustrated in FIG. 1.

FIG. 6 is a timing diagram illustrating an operation example of an amplitude detection circuit illustrated in FIG. 4.

FIG. 7 is a table illustrating an example of impedance settings in the power amplifier illustrated in FIG. 1.

FIG. 8 is a waveform chart illustrating an operation example in the power amplifier illustrated in FIG. 1.

FIG. 9 is another waveform chart illustrating an operation example in the power amplifier illustrated in FIG. 1.

FIG. 10 is another waveform chart illustrating an operation example in the power amplifier illustrated in FIG. 1.

FIG. 11 is another waveform chart illustrating an operation example in the power amplifier illustrated in FIG. 1.

FIG. 12 is a waveform chart illustrating an operation example of another impedance settings in the power amplifier illustrated in FIG. 1.

FIG. 13 is another waveform chart illustrating an operation example of another impedance settings in the power amplifier illustrated in FIG. 1.

FIG. 14 is another waveform chart illustrating an operation example of another impedance settings in the power amplifier illustrated in FIG. 1.

FIG. 15 is another waveform chart illustrating an operation example of the other impedance settings in the power amplifier illustrated in FIG. 1.

FIG. 16 is a circuit diagram illustrating a configuration example of a power amplifier according to a modification example.

FIG. 17 is a circuit diagram illustrating a configuration example of a power amplifier according to another modification example.

FIG. 18 is a perspective view of an appearance configuration of a smartphone to which the power amplifier according to the embodiment is applied.

### MODES FOR CARRYING OUT THE INVENTION

In the following, an embodiment of the present disclosure is described in detail with reference to the drawings. It is to be noted that description is given in the following order.
1. Embodiment
2. Application Example

### 1. Embodiment

### Configuration Example

FIG. 1 illustrates a configuration example of a power amplifier (power amplifier 1) according to an embodiment. The power amplifier 1 is provided in, for example, a smartphone configured to perform wireless communications in a fifth generation (5G) mobile communication system. The power amplifier 1 includes an input terminal Tin, a matching circuit 11, a bias circuit 12, a resistive element R1, a transistor FET1, an inductor L1, a capacitor C1, an inductor L2, a transistor FET2, a capacitor C2, a resistive element R2, an inductor L3, a matching circuit 13, an output terminal Tout, and an impedance control circuit 14.

The input terminal Tin is configured to be supplied with an input signal Sin from a pre-stage circuit of the power amplifier 1. The power amplifier 1 generates an output signal Sout by performing a power amplification operation on the basis of this input signal Sin.

The matching circuit 11 is configured to perform impedance matching of an input of the transistor FET1. The matching circuit 11 includes one or a plurality of capacitors and one or a plurality of inductors, for example. The matching circuit 11 is able to change an impedance of the matching circuit 11 by changing the impedance of one or a plurality of devices of the one or the plurality of capacitors and the one or the plurality of inductors, on the basis of a control signal supplied from the impedance control circuit 14. An input terminal of the matching circuit 11 is coupled to the input terminal Tin of the power amplifier 1, and an output terminal is coupled to the resistive element R1 and a gate of the transistor FET1.

The bias circuit 12 is configured to generate a bias voltage Vg.

The bias voltage Vg is supplied to one end of the resistive element R1, and another end is coupled to the output terminal of the matching circuit 11 and the gate of the transistor FET1.

The gate of the transistor FET1 is coupled to the output terminal of the matching circuit 11 and the resistive element R1, a source is grounded, and a drain is coupled to the capacitor C1 and the inductor L1.

A power supply voltage VDD is supplied to one end of the inductor L1, and another end is coupled to the drain of the transistor FET1 and the capacitor C1.

The capacitor C1 is configured to change the impedance on the basis of the control signal supplied from the impedance control circuit 14. The capacitor C1 includes, for example, a plurality of capacitors, as described below, and is able to change the impedance by changing a number of the capacitors to be used among the plurality of capacitors. One end of the capacitor C1 is coupled to a source of the transistor FET2 and the inductor L2, and another end is coupled to the drain of the transistor FET1 and the inductor L1.

The inductor L2 is configured to change the impedance on the basis of the control signal supplied from the impedance control circuit 14. The inductor L2 includes, for example, a plurality of inductors, as described below, and is able to change the impedance by changing a number of inductors to be used among the plurality of inductors. One end of the inductor L2 is coupled to a source of the transistor FET2 and the capacitor C1, and another end is grounded.

A gate of the transistor FET2 is coupled to the capacitor C2 and the resistive element R2, the source is grounded to the capacitor C1 and the inductor L2, and a drain is coupled to the inductor L3 and an input terminal of the matching circuit 13.

The capacitor C2 is configured to change the impedance on the basis of the control signal supplied from the impedance control circuit 14. The capacitor C2 includes, for example, a varactor, and is able to change the impedance by changing a bias voltage of the varactor, as described below. One end of the capacitor C2 is coupled to the gate of the transistor FET2 and the resistive element R2, and another end is grounded.

The bias voltage Vg is supplied to one end of the resistive element R2, and another end is coupled to the capacitor C2 and the gate of the transistor FET2.

The power supply voltage VDD is supplied to one end of the inductor L3, and another end is coupled to the drain of the transistor FET2 and the input terminal of the matching circuit 13.

The matching circuit 13 is configured to perform the impedance matching of an output of the transistor FET2. The matching circuit 13 includes one or a plurality of capacitors and one or a plurality of inductors, for example. The matching circuit 13 is able to change the impedance of the matching circuit 13 by changing the impedance of one or a plurality of devices of the one or the plurality of capacitors and the one or the plurality of inductors, on the basis of the control signal supplied from the impedance control circuit 14. The input terminal of the matching circuit 13 is coupled to the drain of the transistor FET2 and the inductor L3, and an output terminal is coupled to the output terminal Tout of the power amplifier 1.

The output terminal Tout is configured to output the output signal Sout generated by the power amplifier 1. The output terminal Tout is coupled to, for example, an antenna, which is not illustrated. As a result, the output signal Sout generated by the power amplifier 1 is transmitted as a wireless signal from the antenna.

With this configuration, the power amplifier 1 uses the two transistors FET1 and FET 2 to perform the power amplification operation on the basis of the input signal Sin.

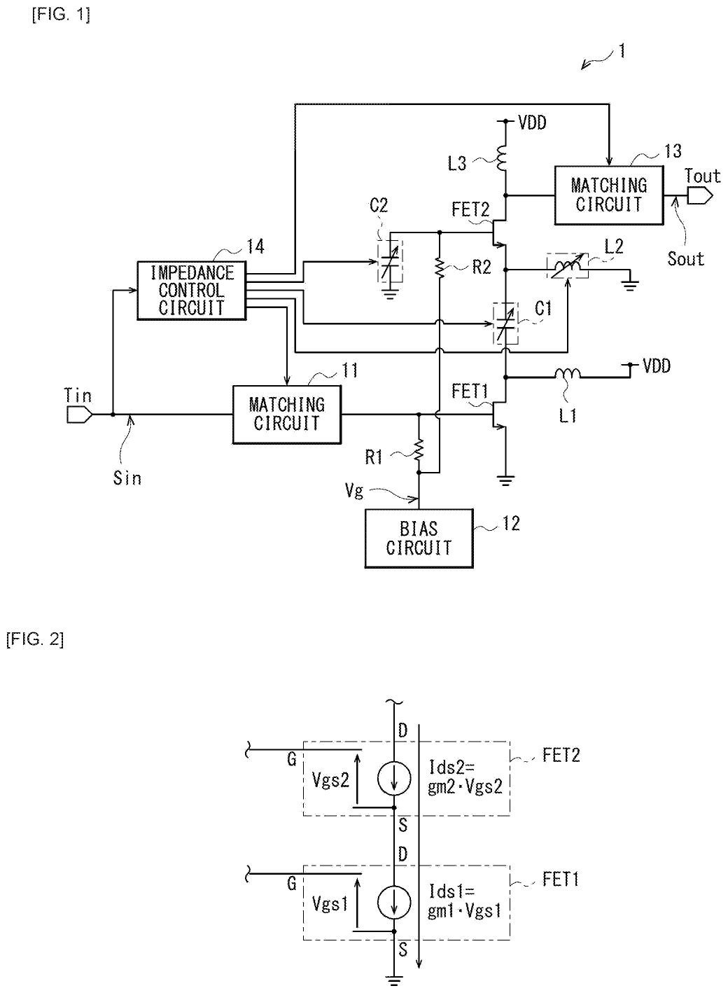

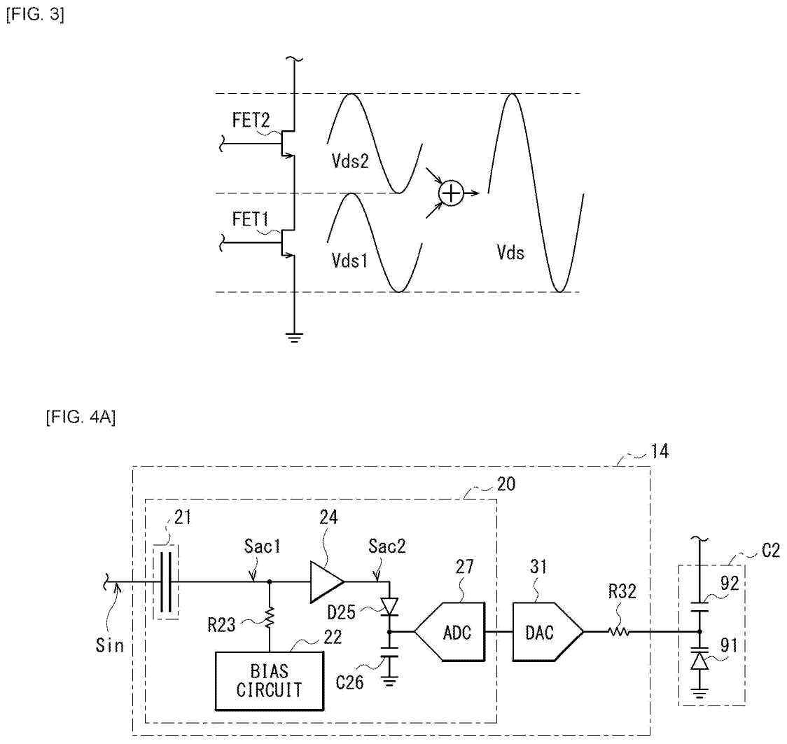

FIG. 2 and FIG. 3 schematically illustrate an operation on an alternating-current signal in the power amplifier 1. In FIG. 2 and FIG. 3, description is given of the operation on the alternating-current signal, and thus, for convenience of explanation, illustration of the capacitor C1 and the inductors L1 and L2 is omitted.

In the power amplifier 1, an ideal case is that a size and characteristics of the transistor FET1 and a size and characteristics of the transistor FET2 are the same as each other. In other words, in this example, current characteristics of the transistor FET1 and current characteristics of the transistor FET2 are the same as each other, and an operating point of the transistor FET1 and the operating point of the transistor FET2 are the same as each other. Specifically, an operating point voltage of the gates of the transistors FET1 and FET2 is the bias voltage Vg, the operating point voltage of the sources is a ground voltage, and the operating point voltage of the drains is the power supply voltage VDD.

Then, as illustrated by an arrow in FIG. 2, an alternating-current signal current corresponding to the input signal Sin flows through the transistors FET1 and FET2. An electric current Ids1 flowing from the drain to the source in the transistor FET1 is expressed as follows by using transconductance gm1 of the transistor FET1 and a voltage Vgs1 between the gate and the source of the transistor FET1:

$$Ids 1 = gm 1 \cdot V gs 1$$

Similarly, an electric current Ids2 flowing from the drain to the source in the transistor FET2 is expressed as follows by using transconductance gm2 of the transistor FET2 and a voltage Vgs2 between the gate and the source of the transistor FET2:

$$Ids 2 = gm 2 \cdot V gs 2$$

Ideally, it is desirable that the power amplifier 1 transmits electric power so that the voltage Vgs1 and the voltage Vgs2 are equal to each other, the electric current Ids1 and the electric current Ids2 are equal to each other, and the voltage Vds1 and the voltage Vds2 are equal to each other. First, using the transistor FET1, the power amplifier 1 amplifies the input signal Sin with Ids1=gm1·Vgs1. Then, using the transistor FET2, the power amplifier 1 amplifies the electric power amplified by the transistor FET1 with a current gain of 1 time and a voltage gain of two times. Specifically, as illustrated in FIG. 3, a voltage Vds outputted by the power amplifier 1 is a total voltage of the voltage Vds1 and the voltage Vds2. Load impedances of the transistors FET1 and FET 2 is adjusted to realize this ideal operation.

The impedance control circuit 14 is configured to detect the signal amplitude of the input signal Sin on the basis of the input signal Sin and generate five control signals for setting the impedance of each of the matching circuit 11, the capacitor C1, the inductor L2, the capacitor C2, and the matching circuit 13, on the basis of that signal amplitude.

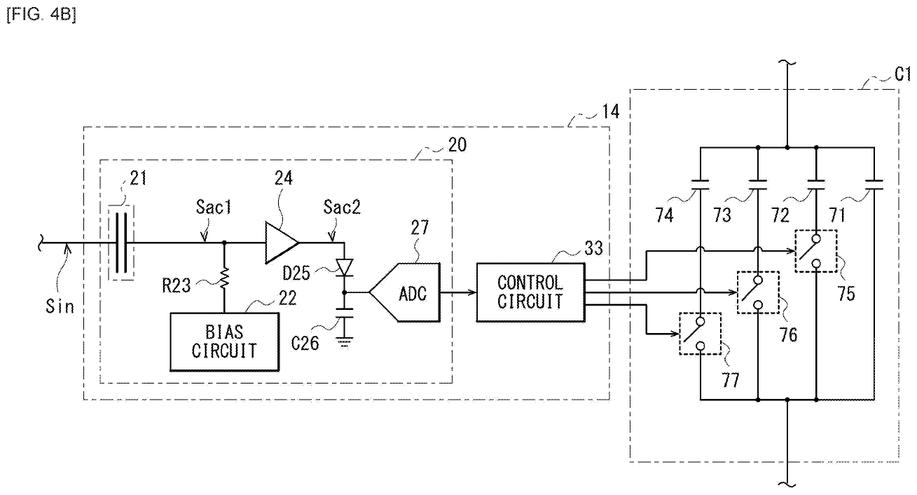

FIG. 4A illustrates a configuration example of a circuit part in the impedance control circuit 14, the circuit part controlling the impedance of the capacitor C2. FIG. 4A also illustrates the capacitor C2. The impedance control circuit 14 includes an amplitude detection circuit 20, a DAC 31, and a resistive element R32.

The amplitude detection circuit 20 includes a coupler 21, a bias circuit 22, a resistive element R23, a buffer amplifier 24, a diode D25, a capacitor C26, and an ADC (Analog to Digital Converter) 27.

The coupler 21 is configured to separate the alternating-current signal contained in the input signal Sin supplied to the input terminal Tin and supply the separated alternating-current signal to the buffer amplifier 24 as an alternating-current signal Sac1. The coupler 21 is configured by using a transmission line, for example.

The bias circuit 22 is configured to generate a bias voltage. The bias voltage generated by the bias circuit 22 is supplied to one end of the resistive element R23, and another end is coupled to an input terminal of the buffer amplifier 24.

The buffer amplifier 24 is configured to generate an alternating-current signal Sac2 that corresponds to the alternating-current signal Sac1. The input terminal of the buffer amplifier 24 is coupled to the coupler 21 and the resistive element R23, and an output terminal is coupled to an anode of the diode D25.

The anode of the diode D25 is coupled to the output terminal of the buffer amplifier 24, and a cathode is coupled to input terminals of the capacitor C26 and the ADC 27. One end of the capacitor 26 is coupled to the cathode of the diode D25 and an input terminal of the ADC 27, and another end is grounded.

The ADC 27 is configured to generate a digital code by performing AD conversion on the basis of a voltage in the capacitor 26. The digital code is a digital code of a plurality of bits, for example. The input terminal of the ADC 27 is coupled to the cathode of the diode D25 and the capacitor C26, and an output terminal is coupled to an input terminal of the DAC 31.

The DAC 31 is configured to generate a voltage on the basis of the digital code generated by the ADC 27. The input terminal of the DAC 31 is coupled to the output terminal of the ADC 27, and an output terminal is coupled to the resistive element R32. One end of the resistive element R32 is coupled to the output terminal of DAC 31, and another end is coupled to the capacitor C2.

With this configuration, for example, in a case where the signal amplitude of the input signal Sin is large, a peak level of the alternating-current signal Sac1 is high. In this case, as the peak level of the alternating-current signal Sac2 is also high, a voltage in the capacitor C26 is high. This increases a value of the digital code generated by the ADC 27. The DAC 31 increases a voltage supplied to the capacitor C2 on the basis of such a digital code. In addition, for example, in a case where the signal amplitude of the input signal Sin is small, the peak level of the alternating-current signal Sac1 is low. In this case, as the peak level of the alternating-current signal Sac2 is also low, the voltage in the capacitor C26 is low. Consequently, the value of the digital code generated by the ADC 27 is small. The DAC 31 decreases the voltage supplied to the capacitor C2 on the basis of such a digital code.

In this example, the voltage supplied to the capacitor C2 is increased in a case where the signal amplitude of the input signal Sin is large, and the voltage supplied to the capacitor C2 is decreased in a case where the signal amplitude of the input signal Sin is small. However, the embodiment is not limited to this. For example, a logic circuit that converts a digital code may be provided between the ADC 27 and the DAC 31. This makes it possible to decrease the voltage supplied to the capacitor C2 in a case where the signal amplitude of the input signal Sin is large and to increase the voltage supplied to the capacitor C2 in a case where the signal amplitude of the input signal Sin is low, for example.

The capacitor C2 includes a varactor 91 and a capacitor 92 in this example. The varactor 91 is configured to change a capacitance value according to a voltage difference between both ends. An anode of the varactor 91 is grounded, and a cathode is coupled to the resistive element R32 and the capacitor 92. The one end of the capacitor C2 is coupled to the resistive element R32 and the cathode of the varactor 91, and the other end is coupled to the gate of the transistor FET2 and the resistive element R2, as illustrated in FIG. 1. The varactor 91 and the capacitor 92 are coupled in series to each other. Consequently, a capacitance of the capacitor C2 is combined capacitances of the serially connected varactor 91 and capacitor 92.

For example, this configuration makes the capacitance of the varactor 91 smaller as a cathode voltage of the varactor 91 is higher. Thus, the combined capacitances of the serially connected varactor 91 and capacitor 92 also becomes smaller. In addition, for example, the capacitance of the varactor 91 is larger as the cathode voltage of the varactor 91 is lower. Thus, the combined capacitances of the serially connected varactor 91 and capacitor 92 also becomes larger. As such, the capacitor C2 is able to change the impedance by changing the capacitance of the varactor 91.

FIG. 4B illustrates a configuration example of the circuit part in the impedance control circuit 14, the circuit part controlling the impedance of the capacitor C1. The impedance control circuit 14 includes a control circuit 33. FIG. 4B also illustrates the capacitor C1.

The control circuit 33 is configured to generate three control signals for switching the impedance of the capacitor C1 on the basis of the digital code generated by the ADC 27.

The capacitor C1 includes capacitors 71 to 74 and switches 75 to 77. One end of the capacitor 71 is coupled to the capacitors 72 to 74 and coupled to the source of the transistor FET2 and the inductor L2, as illustrated in FIG. 1. Another end is coupled to the switches 75 to 77 and coupled to the drain of the transistor FET1 and the inductor L1, as illustrated in FIG. 1. One end of the capacitor 72 is coupled to the capacitors 71, 73, and 74 and coupled to the source of the transistor FET2 and the inductor L2, as illustrated in FIG. 1, and another end is coupled to the switch 75. One end of the capacitor 73 is coupled to the capacitors 71, 72, and 74 and coupled to the source of the transistor FET2 and the inductor L2, and another end is coupled to the switch 76, as illustrated in FIG. 1. One end of the capacitor 74 is coupled to the capacitors 71 to 73 and coupled to the source of the transistor FET2 and the inductor L2, and another end is coupled to the switch 77, as illustrated in FIG. 1. The switch 75 is configured to be coupled to the other end of the capacitor 72 and the other end of the capacitor 71, by turning on, on the basis of a control signal supplied from the control circuit 33. The switch 76 is configured to couple and ground the other end of the capacitor 73 and the other end of the capacitor 71 by turning on, on the basis of the control signal supplied from the control circuit 33. The switch 77 is configured to couple the other end of the capacitor 74 and the other end of the capacitor 71, by turning on, on the basis of the control signal supplied from the control circuit 33.

For example, this configuration enables the capacitor 72 in a case where the switch 75 is in the on state, enables the capacitor 73 in a case where the switch 76 is in the on state, and enables the capacitor 74 in a case where the switch 77 is in the on state. The capacitor 71 is enabled constantly. Therefore, a capacitance of the capacitor C1 is a total of capacitances of the enabled capacitor among the capacitors 71 to 74. In this manner, the capacitor C1 is able to change the impedance by changing the number of the capacitors to be enabled among the capacitors 71 to 74.

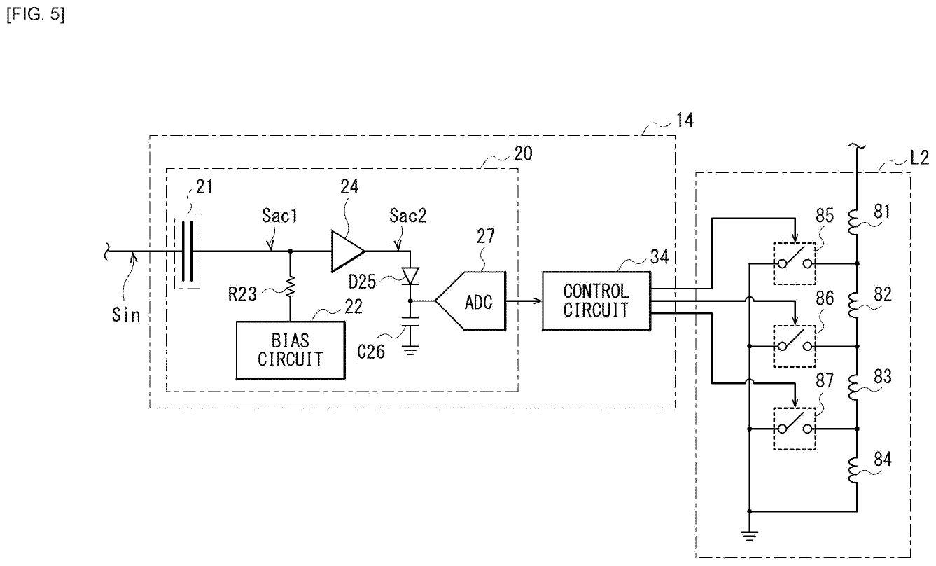

FIG. 5 illustrates a configuration example of the circuit part in the impedance control circuit 14, the circuit part controlling the impedance of the inductor L2. The impedance control circuit 14 includes a control circuit 34. FIG. 5 also illustrates the inductor L2.

The control circuit 34 is configured to generate three control signals for switching the impedance of the inductor L2 on the basis of the digital code generated by the ADC 27.

The inductor L2 includes inductors 81 to 84 and switches 85 to 87. As illustrated in FIG. 1, one end of the inductor 81 is coupled to the source of the transistor FET2 and the capacitor C1, and another end is coupled to one end of the inductor 82. The one end of the inductor 82 is coupled to the other end of the inductor 81, and another end is coupled to one end of the inductor 83. The one end of the inductor 83 is coupled to the other end of the inductor 82, and another end is coupled to one end of the inductor 84. The one end of the inductor 84 is coupled to the other end of the inductor 83, and another end is grounded. The switch 85 is configured to ground the other end of the inductor 81 and the one end of the inductor 82 by turning on, on the basis of a control signal supplied from the control circuit 34. The switch 86 is configured to ground the other end of the inductor 82 and the one end of the inductor 83 by turning on, on the basis of the control signal supplied from the control circuit 34. The switch 87 is configured to ground the other end of the inductor 83 and the one end of the inductor 84 by turning on, on the basis of the control signal supplied from the control circuit 34.

This configuration enables the inductor 81 and disables the inductors 82 to 84, for example, in a case where the switch 85 is in the on state. Therefore, an inductance of the inductor L2 equals to the inductance of the inductor 81. In addition, for example, in a case where the switch 85 is in an off state and the switch 86 is in the on state, the inductors 81 and 82 are enabled and the inductors 83 and 84 are disabled. Therefore, the inductance of the inductor L2 is a total inductance of the inductances of the inductors 81 and 82. In addition, for example, in a case where the switches 85 and 86 are in the off state and the switch 87 is in the on state, the inductors 81 to 83 are enabled and the inductor 84 is disabled. Therefore, the inductance of the inductor L2 is the total inductance of the inductances of the inductors 81 to 83. In addition, for example, in a case where the switches 85 to 87 are in the off-state, the inductors 81 to 84 are enabled. Therefore, the inductance of the inductor L2 is the total inductance of the inductances of the inductors 81 to 84. In this manner, the inductor L2 is able to change the impedance by changing the number of inductors to be enabled among the inductors 81 to 84.

In FIG. 4A, description is given of the circuit part that controls the impedance of the capacitor C2. In FIG. 4B, description is given of the circuit part that controls the impedance of the conductor C1. In FIG. 5, description is given of the circuit part that controls the impedance of the inductor L2. However, the same applies to the circuit part that controls the impedance of the matching circuit 11. In other words, the matching circuit 11 includes, for example, the one or the plurality of capacitors and the one or the plurality of inductors, and is able to change the impedance of the matching circuit 11 by changing the impedance of one or a plurality of these devices. Therefore, it is possible to control the impedance of the matching circuit 11 by applying the configurations illustrated in FIG. 4A, FIG. 4B, and FIG. 5. The same also applies to the matching circuit 13.

This configuration allows the power amplifier 1 to set the impedance of each of the matching circuit 11, the capacitor C1, the inductor L2, the capacitor C2, and the matching circuit 13, in accordance with the signal amplitude of the input signal Sin. As a result of the power amplifier 1 setting the impedances of the matching circuit 11, the capacitor C1, the inductor L2, the capacitor C2, and the matching circuit 13, the operating conditions of the transistors FET1 and FET2 are set. Therefore, in a case where the input signal Sin with various signal amplitudes is inputted, the power amplifier 1 is able to perform a desired power amplification operation without relying on the signal amplitude.

Here, the input terminal Tin corresponds to a specific example of the “input terminal” in the present disclosure. The output terminal Tout corresponds to a specific example of the “output terminal” in the present disclosure. The transistors FET1 and FET2 each correspond to a specific example of the “one or the plurality of transistors” in the present disclosure. The transistor FET1 corresponds to a specific example of a “first transistor” in the present disclosure. The transistor FET2 corresponds to a specific example of a “second transistor” in the present disclosure. The amplitude detection circuit 20 corresponds to a specific example of an “amplitude detection circuit” in the present disclosure. The matching circuit 11, the capacitor C1, the inductor L2, the capacitor C2, and the matching circuit 13 each corresponds to a specific example of an “impedance circuit” in the present disclosure. The coupler 21 corresponds to a specific example of a “separation device” in the present disclosure. The buffer amplifier 24 corresponds to a specific example of a “buffer amplifier” in the present disclosure. The diode D25 corresponds to a specific example of a “diode” in the preset disclosure. The capacitor C26 corresponds to a specific example of a “first capacitor” in the present disclosure.

### [Operations and Workings]

In the following, description is given of operations and workings of the power amplifier 1 of this embodiment.

### Overview of Overall Operation

First, an overview of overall operation of the power amplifier 1 is described with reference to FIG. 1. The power amplifier 1 generates the output signal Sout by performing the power amplification operation on the basis of the input signal Sin. The impedance control circuit 14 detects the signal amplitude of the input signal Sin on the basis of the input signal Sin, and generates five control signals for setting the impedance of each of the matching circuit 11, the capacitor C1, the inductor L2, the capacitor C2, and the matching circuit 13 on the basis of that signal amplitude. The matching circuit 11 changes the impedance on the basis of the control signal supplied from the impedance control circuit 14. The capacitor C1 changes the impedance on the basis of the control signal supplied from the impedance control circuit 14. The inductor L2 changes the impedance on the basis of the control signal supplied from the impedance control circuit 14. The capacitor C2 changes the impedance on the basis of the control signal supplied from the impedance control circuit 14. The matching circuit 13 changes the impedance on the basis of the control signal supplied from the impedance control circuit 14.

### Detailed Operation

The power amplifier 1 causes the impedances of the matching circuit 11, the capacitor C1, the inductor L2, the capacitor C2, and the matching circuit 13 to vary on the basis of the signal amplitude of the input signal Sin. In the following, with reference to FIG. 4, description is given with an operation to cause the impedance of the capacitor C2 to vary as an example.

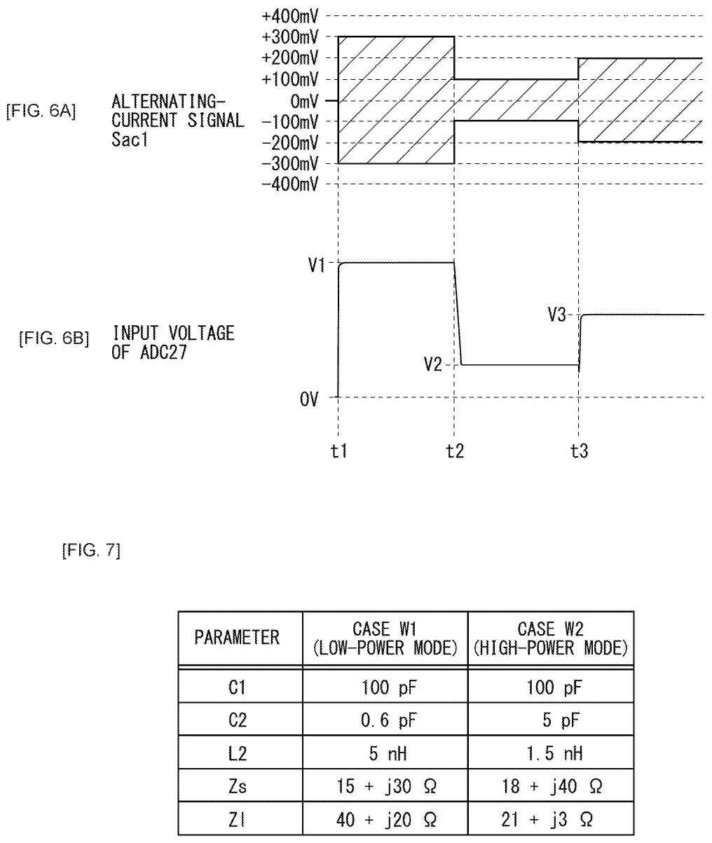

FIG. 6 illustrates an example of an operation of the amplitude detection circuit 20 in the impedance control circuit 14. (A) in FIG. 6 illustrates an envelope of the alternating-current signal Sac1, and (B) in FIG. 6 illustrates an input voltage of the ADC 27.

In this example, at timing t1, the signal amplitude of the input signal Sin becomes 600 mVpp. The coupler 21 separates an alternating-current signal contained in the input signal Sin. This makes the peak level of the separated alternating-current signal “+300 mV” and a bottom level “−300 mV”, as illustrated in FIG. 6(A). The buffer amplifier 24 generates the alternating-current signal Sac2 corresponding to the alternating-current signal Sac1, and the diode D25 and the capacitor C26 perform a peak hold operation. This makes the input voltage of the ADC 27 a voltage (voltage V1) corresponding to the peak level of the alternating-current signal Sac1, as illustrated in FIG. 6(B). The ADC 27 generates a digital code by performing the AD conversion on the basis of this input voltage, and the DAC 31 generates a voltage on the basis of the digital code generated by the ADC 27. This makes the cathode voltage of the varactor 91 a voltage corresponding to the voltage V1. As a result, the capacitance of the capacitor C2 including the varactor 91 becomes a capacitance corresponding to this cathode voltage.

Next, at timing t2, the signal amplitude of the input signal Sin changes from 600 mVpp to 200 mVpp. This makes the peak level of the separated alternating-current signal Sac1 “+100 mV” and the bottom level “−100 mV”, as illustrated in FIG. 6(A). The buffer amplifier 24 generates the alternating-current signal Sac2 corresponding to the alternating-current signal Sac1, and the diode D25 and the capacitor C26 perform the peak hold operation. This makes the input voltage of the ADC 27 the voltage corresponding to the peak level of the alternating-current signal Sac1. In this example, because the peak level decreases from “+300 mV” to “+100 mV”, the input voltage of the ADC 27 also decreases to a voltage V2, as illustrated in FIG. 6(B). The ADC 27 generates a digital code by performing the AD conversion on the basis of this input voltage, and the DAC 31 generates a voltage on the basis of this digital code. This makes the cathode voltage of the varactor 91 a voltage corresponding to the voltage V2. As a result, the capacitance of the capacitor C2 including the varactor 91 becomes the capacitance corresponding to this cathode voltage.

Next, at timing t3, the signal amplitude of the input signal Sin changes from 200 mVpp to 400 mVpp. This makes the peak level of the separated alternating-current signal Sac1 “+200 mV” and the bottom level “−200 mV”, as illustrated in FIG. 6(A). The buffer amplifier 24 generates the alternating-current signal Sac2 corresponding to the alternating-current signal Sac1, and the diode D25 and the capacitor C26 perform the peak hold operation. This makes the input voltage of the ADC 27 the voltage corresponding to the peak level of the alternating-current signal Sac1. In this example, because the peak level increases from “+100 mV” to “+200 mV”, the input voltage of the ADC 27 also increases to a voltage of V3, as illustrated in FIG. 6(B). The ADC 27 generates a digital code by performing the AD conversion on the basis of this input voltage, and the DAC 31 generates a voltage on the basis of this digital code. This makes the cathode voltage of the varactor 91 a voltage corresponding to the voltage V3. As a result, the capacitance of the capacitor C2 including the varactor 91 becomes the capacitance corresponding to this cathode voltage.

In this manner, the power amplifier 1 causes the impedance of the capacitor C2 to vary by changing the capacitance of the capacitor C2 in accordance with the signal amplitude of the input signal Sin.

In this example, although description is given with the operation to cause the impedance of the capacitor C2 to vary as an example, the same also applies to the operation to cause the impedance of each of the capacitor C1, the inductor L2, and the matching circuits 11 and 13 to vary.

Next, description is given of the power amplification operation in the power amplifier 1. In this example, description is given of examples of setting the impedance of each of the capacitor C1, the inductor L2, and the matching circuits 11 and 13 in two cases: a case of low-power mode (case W1) in which the signal amplitude of the input signal Sin is small and a case of high-power mode (case W2) in which the signal amplitude of the input signal is large. In this example, the transistors FET1 and FET 2 are HEMTs (High Electron Mobility Transistors) that use gallium nitride (GaN). In this example, the operating point is set so that the power amplifier 1 performs so-called an AB class operation.

As illustrated in FIG. 7, in case W1, the capacitance of the capacitor C1 is “100 pF”, the capacitance of the capacitor C2 is “0.6 pF”, the inductance of the inductor L2 is “5 nH”, the impedance Zs of the matching circuit 11 is “15+j30Ω”, the impedance Z1 of the matching circuit 11 is “40+j20Ω”, and the impedance of the matching circuit 13 is “40+j20Ω”. Here, the impedance Zs is the impedance of the matching circuit 11 viewed from the gate of the transistor FET1, and the impedance Z1 is the impedance of the matching circuit 13 viewed from the drain of the transistor FET2.

In addition, in case W2, the capacitance of the capacitor C1 is “100 pF”, the capacitance of the capacitor C2 is “5 pF”, the inductance of the inductor L2 is “1.5 nH”, the impedance Zs of the matching circuit 11 is “18+j40Ω”, and the impedance Z1 of the matching circuit 13 is “21+j3Ω”.

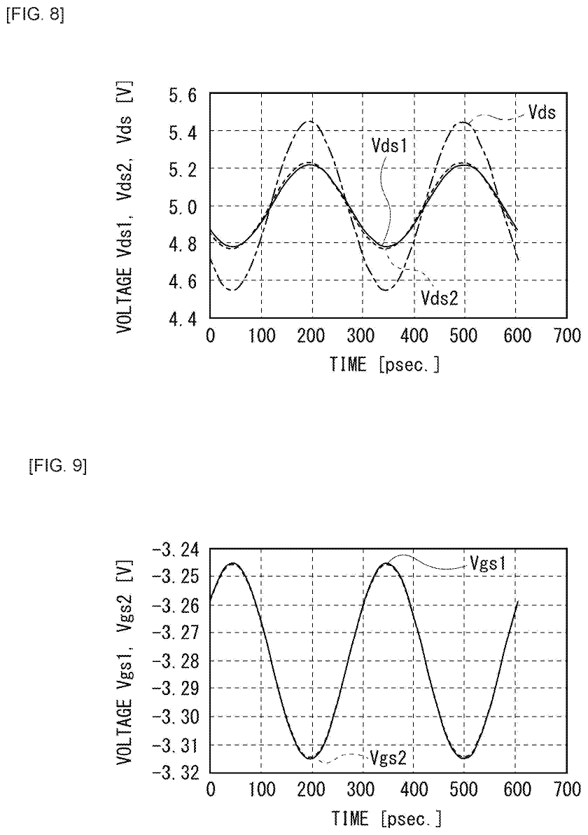

FIG. 8 and FIG. 9 illustrate a result of circuit simulation in a case where the signal amplitude of the input signal Sin is small (case W1). FIG. 8 illustrates waveforms of drain-source voltages Vds1, Vds2, and Vds. FIG. 9 illustrates waveforms of gate-source voltages Vgs1 and Vgs2. The voltage Vds1 is the drain-source voltage of the transistor FET1. The voltage Vds2 is the drain-source voltage of the transistor FET2. The voltage Vds is a voltage between the drain of the transistor FET2 and the source of the transistor FET1. The voltage Vgs1 is the gate-source voltage of the transistor FET1. The voltage Vg2 is the gate-source voltage of the transistor FET2.

In this example, as illustrated in FIG. 2 and FIG. 3, an amplitude of the voltage Vgs1 and an amplitude of the voltage Vgs2 are substantially same as each other, and an amplitude of the voltage Vds1 and an amplitude of the voltage Vds2 are substantially the same as each other. Then, the amplitude of the voltage Vds is substantially twice the amplitude of the voltage Vds1 and the amplitude of the voltage Vds2. That is, by performing the impedance setting corresponding to case W1 (FIG. 7), the power amplifier 1 is able to operate as expected.

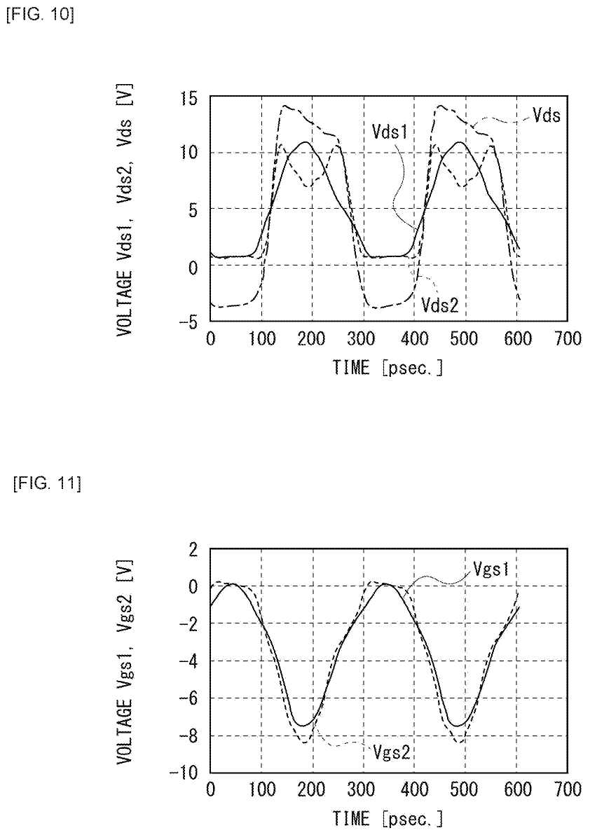

FIG. 10 and FIG. 11 illustrate the result of the circuit simulation in a case where the signal amplitude of the input signal Sin is large (case W2). FIG. 10 illustrates the waveforms of the drain-source voltages Vds1, Vds2, and Vds. FIG. 11 illustrates the waveforms of the gate-source voltages Vgs1 and Vgs2. In this example, because the signal amplitude of the input signal Sin is increased to an amplitude that reaches a saturation region of the power amplifier 1, each of the waveforms is distorted. Even in such a case, the amplitude of the voltage Vgs1 and the amplitude of the voltage Vgs2 are substantially the same as each other, and the amplitude of the voltage Vds1 and the amplitude of the voltage Vds2 are substantially the same as each other. Then, the amplitude of the voltage Vds is substantially twice the amplitude of the voltage Vds1 and the amplitude of the voltage Vds2. That is, by performing the impedance setting corresponding to case W2 (FIG. 7), the power amplifier 1 is able to operate as expected.

In this manner, the power amplifier 1 includes the two transistors FET1 and FET2 provided in the path that couples the input terminal Tin and the output terminal Tout; the amplitude detection circuit 20 configured to detect the signal amplitude of the input signal Sin at the input terminal Tin; and the impedance circuit configured to change the impedance and set the operating conditions of the two transistors FET1 and FET2 on the basis of a detection result of the amplitude detection circuit 20. Here, the impedance circuit includes the matching circuit 11, the capacitor C1, the inductor L2, the capacitor C2, and the matching circuit 13 in this example. Consequently, in a case where the input signal Sin with the various signal amplitudes is inputted, the power amplifier 1 is able to perform the desired power amplification operation without relying on the signal amplitude.

That is, for example, in a case where the impedance setting of the matching circuit 11, the capacitor C1, the inductor L2, the capacitor C2, and the matching circuit 13 is fixed, it is difficult for the power amplifier 1 to perform the desired power amplification operation in a case where the input signal Sin with the various signal amplitudes is inputted.

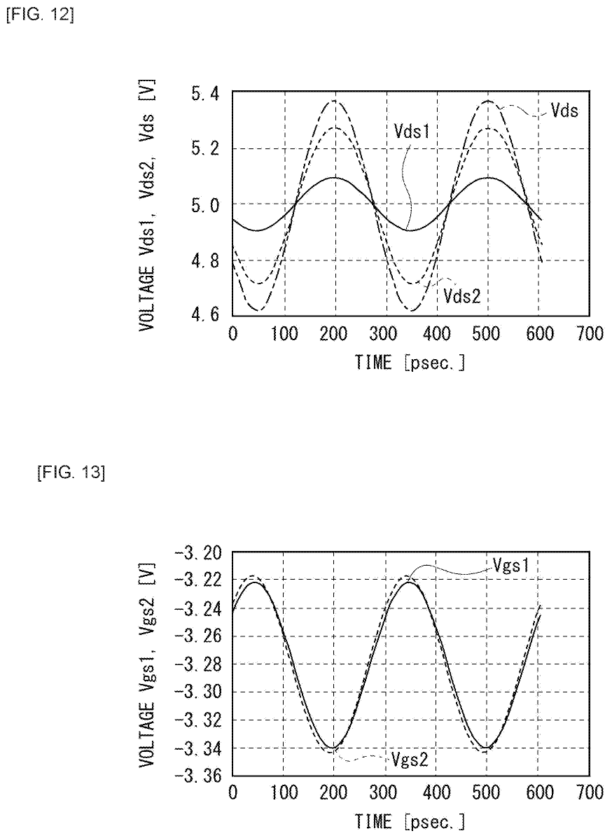

For example, in a case where the input signal Sin having the small signal amplitude is inputted using the impedance setting of the case (case W2) where the signal amplitude of the input signal is large, as illustrated in FIG. 7, it is not possible to perform the desired power amplification operation, as illustrated in FIG. 12 and FIG. 13. In this example, the amplitude of the voltage Vds1 and the amplitude of the voltage Vds2 differ from each other. As such, with the impedance setting that makes it possible to perform the desired power amplification operation in the case (case W2) where the signal amplitude of the input signal Sin is large, the power amplifier 1 is not able to perform the desired power amplification operation in a case where the signal amplitude of the input signal Sin is small.

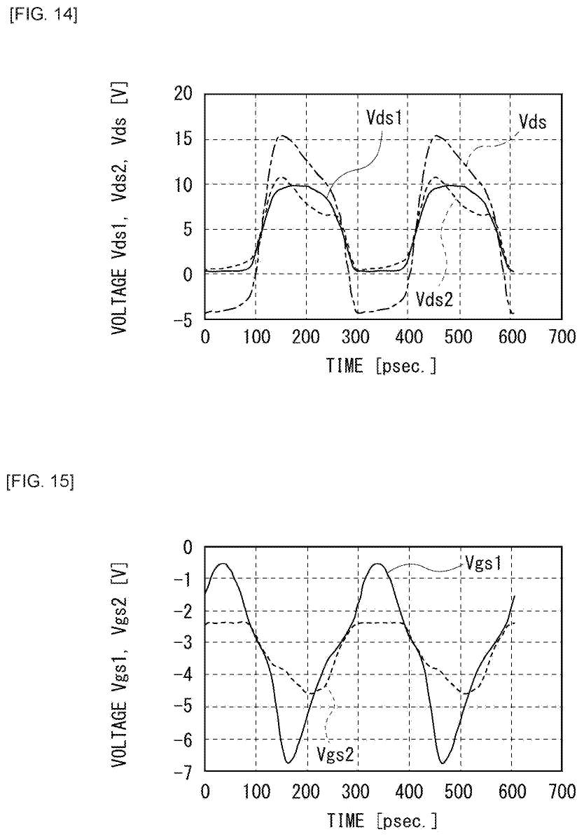

In addition, for example, in a case where the input signal Sin having the large signal amplitude is inputted using the impedance setting of the case (case W1) where the signal amplitude of the input signal Sin is small, as illustrated in FIG. 7, it is not possible to perform the desired power amplification operation, as illustrated in FIG. 14 and FIG. 15. In this example, the amplitude of the voltage Vgs1 and the amplitude of the voltage Vgs2 differ from each other. In addition, as compared with the voltage Vds2 illustrated in FIG. 10, the voltage Vds2 has a larger voltage amplitude at the time of rising and lower symmetry in a time-axis direction. As such, with the impedance setting that makes it possible to perform the desired power amplification operation in the case (case W1) where the signal amplitude of the input signal Sin is small, the power amplifier 1 is not able to perform the desired power amplification operation in a case where the signal amplitude of the input signal Sin is large.

In contrast, the power amplifier 1 includes the impedance circuit configured to change the impedance and set the operating conditions of the two transistors FET1 and FET2 on the basis of the detection result of the amplitude detection circuit 20. This allows the power amplifier 1 to set the operating conditions of the two transistors FET1 and FET2, by setting the impedances of the matching circuit 11, the capacitor C1, the inductor L2, the capacitor C2, and the matching circuit 13, in accordance with the signal amplitude. As a result, in a case where the input signal Sin with the various signal amplitudes is inputted, the power amplifier 1 is able to perform the desired power amplification operation without relying on the signal amplitude.

In addition, in the power amplifier 1, the amplitude detection circuit 20 includes the coupler 21 that separates the alternating-current signal Sac1 from the input signal Sin at the input terminal Tin, and detects the signal amplitude of the input signal Sin by detecting the signal amplitude of this alternating-current signal Sac1. In addition, for example, the amplitude detection circuit 20 includes the buffer amplifier 24 including the input terminal and the output terminal coupled to this coupler 21; the diode D25 including the anode and the cathode coupled to the output terminal of the buffer amplifier 24; and the capacitor C26 coupled to the cathode of the diode D25. The amplitude detection circuit 20 detects the signal amplitude of the input signal Sin on the basis of the voltage at the capacitor C26. This allows the power amplifier 1 to detect the signal amplitude of the input signal Sin with a simple configuration.

### [Effects]

As described above, this embodiment includes the two transistors provided in the path that couples the input terminal and the output terminal; the amplitude detection circuit configured to detect the signal amplitude of the input signal at the input terminal; and the impedance circuit configured to change the impedance and set the operating conditions of the two transistors on the basis of the detection result of the amplitude detection circuit 20. Consequently, it is possible to perform the desired power amplification operation without relying on the signal amplitude in a case where the input signal with the various signal amplitudes is inputted.

In this embodiment, the amplitude detection circuit includes the coupler that separates the alternating-current signal from the input signal at the input terminal, and detects the signal amplitude of the input signal by detecting the signal amplitude of this alternating-current signal. In addition, the amplitude detection circuit includes the buffer amplifier including the input terminal and the output terminal coupled to this coupler; the diode including the anode and the cathode coupled to the output terminal of the buffer amplifier; and the capacitor coupled to the cathode of the diode. The amplitude detection circuit detects the signal amplitude of the input signal on the basis of the voltage at the capacitor. This makes it possible to detect the signal amplitude of the input signal with a simple configuration.

### Modification Example 1

In the foregoing embodiment, the two impedance settings are provided that correspond to the two cases of the signal amplitude of the input signal Sin being small and of the signal amplitude being large. However, the embodiment is not limited to this, and three or more impedance settings may be provided instead of this.

### Modification Example 2

In the foregoing embodiment, although the two transistors FET1 and FET2 are provided, the embodiment is not limited to this. Instead of this, for example, one transistor may be provided, or, for example, three or more transistors may be provided. In the following, detailed description is given of a case where three transistors are provided, by way of example.

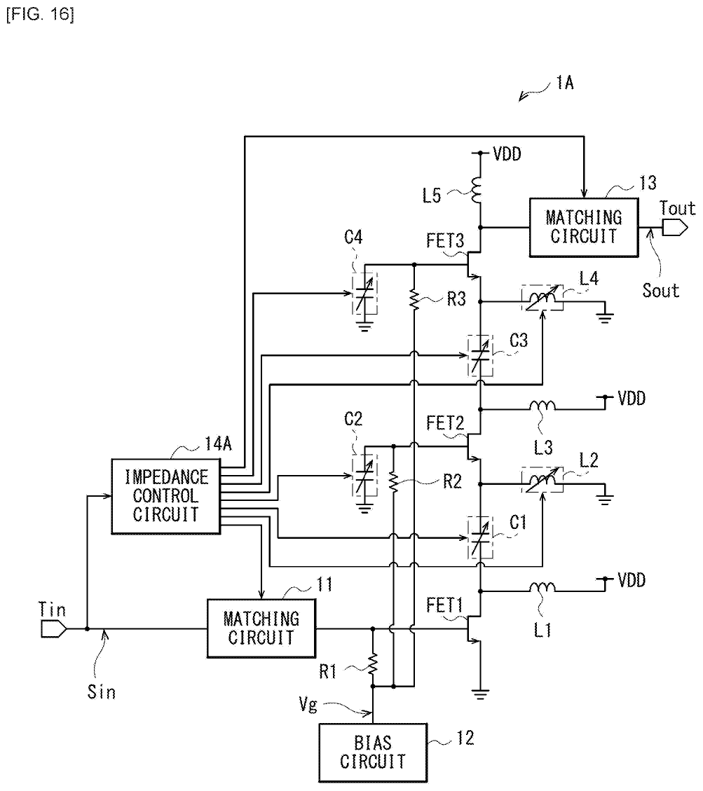

FIG. 16 illustrates a configuration example of a power amplifier 1A according to this modification example. The power amplifier 1A includes a capacitor C3, an inductor LA, a transistor FET3, a capacitor C4, a resistive element R3, an inductor L5, and an impedance control circuit 14A.

The capacitor C3 is configured to change an impedance on the basis of a control signal supplied from the impedance control circuit 14A. Similarly to the capacitor C1, the capacitor C3 includes a plurality of capacitors, for example, and is able to change the impedance by changing the number of capacitors to be used among the plurality of capacitors. One end of the capacitor C3 is coupled to a source of the transistor FET3 and the inductor L4, and another end is coupled to the drain of the transistor FET2 and the inductor L3.

The inductor L4 is configured to change the impedance on the basis of the control signal supplied from the impedance control circuit 14A. Similarly to the inductor L2, the inductor L4 includes a plurality of inductors, for example, and is able to change the impedance by changing the number of inductors to be used among the plurality of inductors. One end of the inductor L4 is coupled to the source of the transistor FET3 and the capacitor C3, and another end is grounded.

A gate of the transistor FET3 is coupled to the capacitor C4 and the resistive element R3, the source is grounded to the capacitor C3 and the inductor L3, and a drain is coupled to input terminals of the inductor L5 and the matching circuit 13.

The capacitor C4 is configured to change the impedance on the basis of the control signal supplied from the impedance control circuit 14A. Similarly to the capacitor C2, the capacitor C4 includes a varactor, for example, and is able to change the impedance by changing the bias voltage of the varactor. One end of the capacitor C4 is coupled to the gate of the transistor FET3 and the resistive element R2, and another end is grounded.

The bias voltage Vg is supplied to one end of the resistive element R3 and another end is coupled to the capacitor C4 and the gate of the transistor FET3.

The power supply voltage VDD is supplied to one end of the inductor L5 and another end is coupled to the drain of the transistor FET3 and the input terminal of the matching circuit 13.

With this configuration, the power amplifier 1A uses the three transistors FET1 to FET 3 to perform the power amplification operation on the basis of the input signal Sin.

The impedance control circuit 14A is configured to detect the signal amplitude of the input signal Sin on the basis of the input signal Sin, and generate eight control signals for setting the impedance of each of the matching circuit 11, the capacitor C1, the inductor L2, the capacitor C2, the capacitor C3, the inductor L4, the capacitor C4, and the matching circuit 13, on the basis of that signal amplitude.

Here, the transistors FET1 to FET3 correspond to a specific example of the “one or the plurality of transistors” in the present disclosure. The matching circuit 11, the capacitor C1, the inductor L2, the capacitor C2, the capacitor C3, the inductor L4, the capacitor C4, and the matching circuit 13 each correspond to a specific example of the “impedance circuit” in the present disclosure.

This allows the power amplifier 1A to perform the desired power amplification operation and to further increase output power, in a case where the input signal of the various signal amplitudes is inputted.

### Modification Example 3

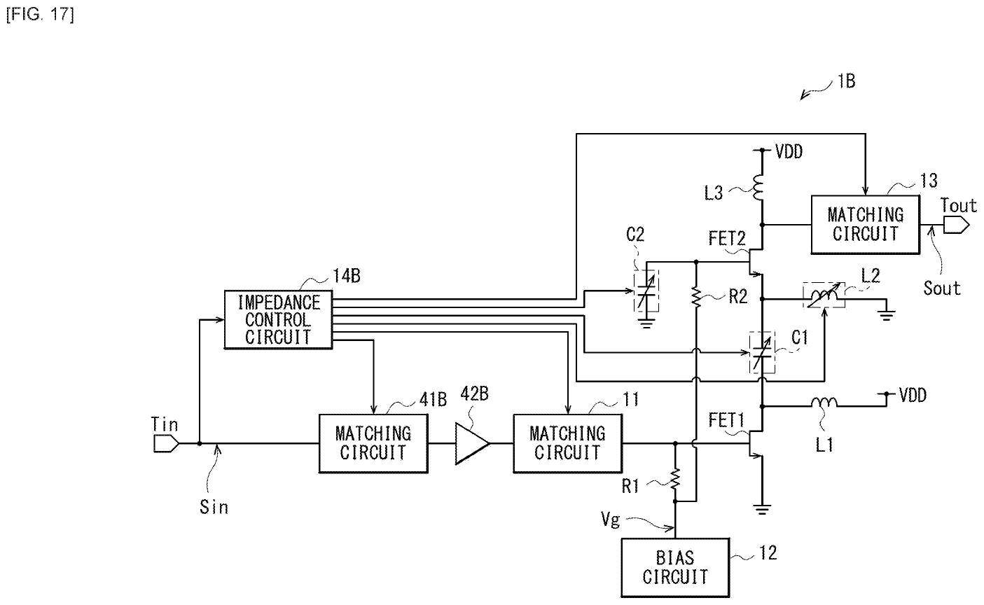

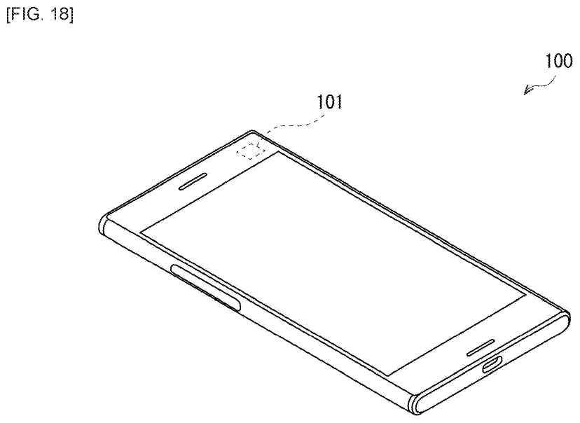

In the foregoing embodiment, the transistors FET1 and FET2 are provided. However, the embodiment is not limited to this, and, for example, a driver amplifier may be provided in this pre-stage, such as a power amplifier 1B as illustrated in FIG. 17, for example. The power amplifier 1B includes a matching circuit 41B, a driver amplifier 42B, and an impedance control circuit 14B.

The matching circuit 41B is configured to perform the impedance matching of input of the driver amplifier 42B. The matching circuit 41B includes one or a plurality of capacitors and one or a plurality of inductors, for example. The matching circuit 41B is able to change the impedance of the matching circuit 41B by changing the impedance of one or more devices of the one or the plurality of capacitors and the one or the plurality of inductors, on the basis of a control signal supplied from the impedance control circuit 14B. An input terminal of the matching circuit 41B is coupled to an input terminal Tin of the power amplifier 1B, and an output terminal is coupled to an input terminal of the driver amplifier 42B.

The driver amplifier 42B is configured to drive the transistor FET1 via the matching circuit 11. The input terminal of the driver amplifier 42B is coupled to the output terminal of the matching circuit 41B, and an output terminal is coupled to the input terminal of the matching circuit 11. Here, the driver amplifier 42B corresponds to a specific example of the “driver amplifier” in the present disclosure.

The impedance control circuit 14B is configured to detect the signal amplitude of the input signal Sin on the basis of the input signal Sin, and generate six control signals for setting the impedance of each of the matching circuit 41B, the matching circuit 11, the capacitor C1, the inductor L2, the capacitor C2, and the matching circuit 13, on the basis of that signal amplitude.

### Other Modification Examples

In addition, two or more of these Modification Examples may be combined.

### 2. Application Examples

In the following, description is given of application examples of the power amplifiers described in the foregoing embodiments and modification examples.

FIG. 18 illustrates an appearance of a smartphone 100 to which the power amplifiers of the foregoing embodiments are applied. In this smartphone 100 is provided a wireless communication circuit 101 that performs communications with a base station. The power amplifier including the foregoing embodiments is applied to this wireless communication circuit 101.

It is possible to apply the power amplifier such as the foregoing embodiments to various electronic apparatus such as tablet terminals, in addition to such a smartphone.

Although description has been given of the technology with reference to the embodiments and the modification examples, as well as specific applications of the embodiments and the modification examples, the technology is not limited to these embodiments or the like, and various modifications may be made thereto.

For example, in the foregoing embodiments or the like, although the technology has been applied to the power amplifers, the technology is not limited to this. It is possible to apply the technology to various amplifers.

It is to be noted that the effects described here are merely illustrative and non-limiting, and may further include other effects.

Moreover, the technology may have the following configurations. According to the technology with the following configuration, it is possible to amplify signals having various signal amplitudes.

(1)

An amplifier circuit including:
an input terminal;
an output terminal;
one or a plurality of transistors provided on a path that couples the input terminal and the output terminal;
an amplitude detection circuit configured to detect a signal amplitude of an input signal at the input terminal; and
an impedance circuit configured to change an impedance and set operating conditions of the one or the plurality of transistors on a basis of a detection result of the amplitude detection circuit.
   (2)

The amplifier circuit according to (1), in which the amplitude detection circuit includes a separation device that separates an alternating-current signal from the input signal, and is configured to detect the signal amplitude of the input signal by detecting a signal amplitude of the alternating-current signal.

(3)

The amplifier circuit according to (2), in which
the amplitude detection circuit includes
   a buffer amplifier including an input terminal coupled to the separation device and an output terminal,
   a diode including an anode coupled to the output terminal of the buffer amplifier and a cathode, and
   a first capacitor coupled to the cathode of the diode, and
the amplitude detection circuit is configured to detect the signal amplitude of the input signal on a basis of a voltage in the first capacitor.
   (4)

The amplifier circuit according to any of (1) to (3), in which the impedance circuit includes a varactor, and is configured to change the impedance by causing a capacitance value in the varactor to vary on the basis of the detection result.

(5)

The amplifier circuit according to (1) to (4), in which the impedance circuit includes a plurality of capacitors, and is configured to change the impedance by selecting one or a plurality of capacitors to be used among the plurality of capacitors on the basis of the detection result.

(6)

The amplifier circuit according to any of (1) to (5), in which the impedance circuit includes a plurality of inductors, and is configured to change the impedance by selecting one or a plurality of inductors to be used among the plurality of inductors on the basis of the detection result.

(7)

The amplifier circuit according to (1), in which
the one or the plurality of transistors includes a first transistor and a second transistor,
the first transistor includes a drain and a gate led to the input terminal, and
the second transistor includes a gate, a drain led to the output terminal, and a source led to the drain of the first transistor.
   (8)

The amplifier circuit according to (7), including
a second capacitor that is coupled to the gate of the second transistor, and is configured to change an impedance, in which
the impedance circuit includes the second capacitor.
   (9)

The amplifier circuit according to (7) or (8), including a first inductor that is coupled to the source of the second transistor, and is configured to change an impedance, in which
the impedance circuit includes the first inductor.
   (10)

The amplifier circuit according to any of (7) to (9), including a third capacitor that is provided on a path coupling the drain of the first transistor and the source of the second transistor, and is configured to change an impedance, in which
the impedance circuit includes the third capacitor.
   (11)

The amplifier circuit according to any of (7) to (10), including a first matching circuit that is provided on a path coupling the input terminal and the gate of the first transistor, and is configured to change an impedance, in which
the impedance circuit includes the first matching circuit.
   (12)

The amplifier circuit according to any of (7) to (10), including:
a driver amplifier provided on a path that couples the input terminal and the gate of the first transistor; and
a first matching circuit provided on a path that couples the driver amplifier and the gate of the first transistor, in which
the impedance circuit includes the first matching circuit.
   (13)

The amplifier circuit according to any of (1) to (12), in which
the one or the plurality of transistors includes a final-stage transistor including a drain,
the amplifier circuit includes a second matching circuit that is provided on a path coupling the drain of the final-stage transistor and the output terminal and is configured to change an impedance, and
the impedance circuit includes the second matching circuit.
   (14)

The amplifier circuit according to any of (1) to (13), in which the amplifier circuit includes a power amplifier.

(15)

An electronic apparatus including a communication circuit that is configured to perform wireless communications, and includes an amplifier circuit,
the amplifier circuit including
   an input terminal,
   an output terminal,
   one or a plurality of transistors provided on a path that couples the input terminal and the output terminal,
   an amplitude detection circuit configured to detect a signal amplitude of an input signal at the input terminal, and
   an impedance circuit configured to change an impedance and set operating conditions of the one or the plurality of transistors on a basis of a detection result of the amplitude detection circuit.

This application claims the benefits of Japanese Priority Patent Application JP2021-088784 filed with the Japan Patent Office on May 26, 2021, the entire contents of which are incorporated herein by reference.

It should be understood that those skilled in the art could conceive various modifications, combinations, sub-combinations, and alterations depending on design requirements and other factors, insofar as they are within the scope of the appended claims or the equivalents thereof.

1. An amplifier circuit comprising:
an input terminal;
an output terminal;
one or a plurality of transistors provided on a path that couples the input terminal and the output terminal;
an amplitude detection circuit configured to detect a signal amplitude of an input signal at the input terminal; and
an impedance circuit configured to change an impedance and set operating conditions of the one or the plurality of transistors on a basis of a detection result of the amplitude detection circuit.

2. The amplifier circuit according to claim 1, wherein the amplitude detection circuit includes a separation device that separates an alternating-current signal from the input signal, and is configured to detect the signal amplitude of the input signal by detecting a signal amplitude of the alternating-current signal.

3. The amplifier circuit according to claim 2, wherein
the amplitude detection circuit includes
a buffer amplifier including an input terminal coupled to the separation device and an output terminal,
a diode including an anode coupled to the output terminal of the buffer amplifier and a cathode, and
a first capacitor coupled to the cathode of the diode, and
the amplitude detection circuit is configured to detect the signal amplitude of the input signal on a basis of a voltage in the first capacitor.

4. The amplifier circuit according to claim 1, wherein the impedance circuit includes a varactor, and is configured to change the impedance by causing a capacitance value in the varactor to vary on the basis of the detection result.

5. The amplifier circuit according to claim 1, wherein the impedance circuit includes a plurality of capacitors, and is configured to change the impedance by selecting one or a plurality of capacitors to be used among the plurality of capacitors on the basis of the detection result.

6. The amplifier circuit according to claim 1, wherein the impedance circuit includes a plurality of inductors, and is configured to change the impedance by selecting one or a plurality of inductors to be used among the plurality of inductors on the basis of the detection result.

7. The amplifier circuit according to claim 1, wherein
the one or the plurality of transistors includes a first transistor and a second transistor,
the first transistor includes a drain and a gate led to the input terminal, and
the second transistor includes a gate, a drain led to the output terminal, and a source led to the drain of the first transistor.

8. The amplifier circuit according to claim 7, comprising a second capacitor that is coupled to the gate of the second transistor, and is configured to change an impedance, wherein
the impedance circuit includes the second capacitor.

9. The amplifier circuit according to claim 7, comprising a first inductor that is coupled to the source of the second transistor, and is configured to change an impedance, wherein
the impedance circuit includes the first inductor.

10. The amplifier circuit according to claim 7, comprising a third capacitor that is provided on a path coupling the drain of the first transistor and the source of the second transistor, and is configured to change an impedance, wherein
the impedance circuit includes the third capacitor.

11. The amplifier circuit according to claim 7, comprising a first matching circuit that is provided on a path coupling the input terminal and the gate of the first transistor, and is configured to change an impedance, wherein
the impedance circuit includes the first matching circuit.

12. The amplifier circuit according to claim 7, comprising:
a driver amplifier provided on a path that couples the input terminal and the gate of the first transistor; and
a first matching circuit provided on a path that couples the driver amplifier and the gate of the first transistor, wherein
the impedance circuit includes the first matching circuit.

13. The amplifier circuit according to claim 1, wherein
the one or the plurality of transistors includes a final-stage transistor including a drain,
the amplifier circuit includes a second matching circuit that is provided on a path coupling the drain of the final-stage transistor and the output terminal and is configured to change an impedance, and
the impedance circuit includes the second matching circuit.

14. The amplifier circuit according to claim 1, wherein the amplifier circuit comprises a power amplifier.

15. An electronic apparatus comprising a communication circuit that is configured to perform wireless communications and includes an amplifier circuit,
the amplifier circuit including
an input terminal,
an output terminal,
one or a plurality of transistors provided on a path that couples the input terminal and the output terminal,
an amplitude detection circuit configured to detect a signal amplitude of an input signal at the input terminal, and
an impedance circuit configured to change an impedance and set operating conditions of the one or the plurality of transistors on a basis of a detection result of the amplitude detection circuit.
